(19) United States
(12) Patent Application Publication
(10) Pub. No.: US 2024/0290847 A1
(43) Pub. Date: Aug. 29, 2024

(54) Electric Field Modification for Nitrogen-Polar Group III-Nitride Semiconductor Devices

(71) Applicant: Wolfspeed, Inc., Durham, NC (US)

(72) Inventors: Kyle Bothe, Cary, NC (US); Chris Hardiman, Cary, NC (US); Scott Sheppard, Chapel Hill, NC (US)

(21) Appl. No.: 18/175,231

(22) Filed: Feb. 27, 2023

(51) Int. Cl. H01L 29/40; H01L 29/20; H01L 29/66; H01L 29/778

(52) U.S. Cl. CPC H01L 29/408; H01L 29/2003; H01L 29/401; H01L 29/66462; H01L 29/7786

(57) ABSTRACT

Semiconductor devices having nitrogen-polar (N-polar) Group III-nitride semiconductor structures are provided. In one example, a semiconductor device may include a nitrogen polar (N-polar) Group III-nitride semiconductor structure. The N-polar Group III-nitride semiconductor structure may have a first surface and a second surface opposing the first surface. The semiconductor device may include an electrode. The semiconductor device may include a low-k dielectric layer located between the first surface of the N-polar Group III-nitride semiconductor structure and at least a portion of the electrode. The low-k dielectric layer may have a dielectric constant of less than about 3.9. In some examples, the N-polar Group III-nitride semiconductor structure may include a trench extending at least partially into one or more cap layers of the N-polar Group III-nitride semiconductor structure.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device may include a nitrogen polar (N-polar) Group III-nitride semiconductor structure. The N-polar Group III-nitride semiconductor structure may have a first surface and a second surface opposing the first surface. The semiconductor device may include an electrode. The semiconductor device may include a low-k dielectric layer located between the first surface of the N-polar Group III-nitride semiconductor structure and at least a portion of the electrode. The low-k dielectric layer may have a dielectric constant of less than about 3.9.

Another example aspect of the present disclosure is directed to a transistor device. The transistor device may include an N-polar Group III-nitride semiconductor structure. The N-polar Group III-nitride semiconductor structure may include a barrier layer, a channel layer on the barrier layer, and one or more cap layers on the channel layer. The transistor device may include a trench extending at least partially into the one or more cap layers of the N-polar Group III-nitride semiconductor structure.

Another example aspect of the present disclosure is directed to a transistor device. The transistor device may include an N-polar Group III-nitride semiconductor structure. The N-polar Group III-nitride semiconductor structure may include a barrier layer and a channel layer on the barrier layer. The transistor device may include a gate contact. The transistor device may include a low-k dielectric layer located between a first surface of the N-polar Group III-nitride semiconductor structure and at least a portion of the gate contact. The low-k dielectric layer may have a dielectric constant of less than about 3.9.

Yet another example aspect of the present disclosure is directed to a method. The method may include forming an N-polar Group III-nitride semiconductor structure. The method may include forming a gate contact on the N-polar Group III-nitride semiconductor structure. The method may include forming a low-k dielectric layer in a space between the N-polar Group III-nitride semiconductor structure and at least a portion of the gate contact. The low-k dielectric layer has a dielectric constant of less than about 3.9.

Yet another example aspect of the present disclosure is directed to a method. The method may include forming an N-polar Group III-nitride semiconductor structure. The N-polar Group III-nitride semiconductor structure may include a barrier layer, a channel layer on the barrier layer, and one or more cap layers on the channel layer. The method may include forming a trench at least partially extending through the one or more cap layers.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts example metal-polar and nitrogen-polar (N-polar) Group-III nitride crystal structures.

FIG. 2 depicts an example semiconductor device according to example embodiments of the present disclosure;

FIG. 3 depicts an example semiconductor device according to example embodiments of the present disclosure;

FIG. 4 depicts an example semiconductor device according to example embodiments of the present disclosure;

FIG. 5 depicts an example semiconductor device according to example embodiments of the present disclosure.

FIG. 6 depicts an example semiconductor device according to example embodiments of the present disclosure;

FIG. 7 depicts an example semiconductor device according to example embodiments of the present disclosure.

FIG. 8 depicts an example semiconductor device according to example embodiments of the present disclosure;

FIG. 9 depicts an example semiconductor device according to example embodiments of the present disclosure;

FIG. 10 depicts a flow chart of an example method according to example embodiments of the present disclosure; and

FIG. 11 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-nitride based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

HEMT devices may include metal-polar (e.g., Ga-polar) or nitrogen-polar (e.g., N-polar) Group III-nitride semiconductor structures. More specifically, Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the Group III-nitride semiconductor structure. A direction associated with the spontaneous polarization dipole may determine whether the Group III-nitride semiconductor structure is metal-polar or N-polar.

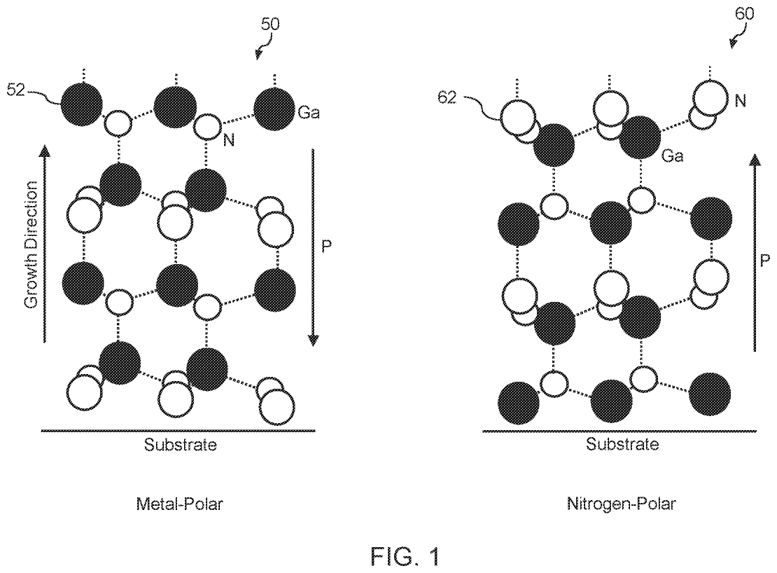

For instance, FIG. 1 depicts an example metal-polar Group III nitride semiconductor structure 50 (e.g., Ga-polar GaN) and an example N-polar Group III-nitride semiconductor structure 60 (e.g., N-polar GaN). As shown, the metal-polar Group III-nitride semiconductor structure 50 and the N-polar Group III-nitride semiconductor structure 60 each have a hexagonal wurtzite crystal structure. In a wurtzite crystal structure, the metal (e.g., gallium) and the nitrogen are arranged in separate distinct layers. The metal-polar (e.g., Ga-polar) Group III-nitride semiconductor structure 50 has a metal face 52 (e.g., gallium face) in the growth direction of the semiconductor structure 50 relative to a substrate. The direction of the spontaneous polarization dipole P may be opposite the growth direction in the metal-polar Group III-nitride semiconductor structure 50. The N-polar semiconductor structure 60 has a nitrogen face 62 in the growth direction of the semiconductor structure 60 relative to a substrate. The direction of the spontaneous polarization dipole P may be the same as the growth direction in the N-polar Group III-nitride semiconductor structure 60.

HEMT devices including N-polar Group III-nitride structures have recently been shown to deliver significant performance advantages, particularly at operating frequencies in the millimeter wave frequency ranges (e.g., 30 GHz or greater) relative to traditional metal-polar Group-III nitride structures. High frequency and/or high-power RF applications for N-polar Group III-nitride based devices may require smaller gate lengths and tighter device tolerances. An electric field induced in the Group III-nitride semiconductor structure and/or parasitic capacitances on the drain side of an HEMT device may reduce performance at high frequencies.

Aspects of the present disclosure are directed to semiconductor devices having an N-polar Group III-nitride semiconductor structure that includes features to reduce a peak electric field in the Group III-nitride semiconductor structure during operation of the device. More particularly, drain side modifications may be made to an HEMT device to reduce the peak electric field and/or parasitic capacitances in devices having N-polar Group III-nitride semiconductor structures.

For instance, in one example, a low-k dielectric layer may be used to reduce the parasitic capacitance of an electrode (e.g., T gate or gamma gate) of the semiconductor device. The low-k dielectric layer may provide enhanced structural rigidity for the device. The low-k dielectric layer may be located between a surface of the N-polar Group III-nitride semiconductor structure and at least a portion of the electrode. The low-k dielectric layer may have a dielectric constant less than a dielectric constant of silicon dioxide (SiO₂). For instance, the low-k dielectric layer may have a dielectric constant of less than about 3.9, such as in a range of greater than 1 and less than 3.9. In some examples, the low-k dielectric layer may include one or more of a doped silicon dioxide, a porous silicon dioxide, an organic material, or a silicon-based polymeric material.

In some embodiments, the semiconductor device may include a trench extending at least partially into the N-polar Group III-nitride structure (e.g., on the drain side of the semiconductor device). For instance, the semiconductor device may include a trench extending at least partially into one or more cap layers of the device. The trench can have a lateral width extending between a gate contact and a drain contact. In some examples, the lateral width may be at least 50% of a distance between the gate contact and the drain contact, such as at least 75% of the distance between the gate contact and the drain contact, such as at least 85% of the distance between the gate contact and the drain contact, such as at least 90% of the distance between the gate contact and the drain contact. For instance, the lateral width can be about 0.25 μm to about 2 μm.

In some examples, the trench may extend to a depth of about 250 Angstroms to about 1000 Angstroms from a surface of the N-polar Group III-nitride structure, such as about 250 Angstroms to about 500 Angstroms from a surface of the N-polar Group III-nitride semiconductor structure. In some examples the trench may extend to a depth within about 250 Angstroms or less of a channel layer in the N-polar Group III-nitride semiconductor structure, such as about 100 Angstroms or less, such as about 50 Angstroms or less, such as about 30 Angstroms or less.

In some examples, the trench may have a sloped lower surface that extends between, for instance, a gate contact and a drain contact for the semiconductor device. In some examples, the sloped lower surface may have a negative slope towards the gate contact. In some examples, the sloped lower surface may have a negative slope towards the drain contact.

In some examples, the semiconductor device may include one or more dielectric layers on the trench. For instance, the semiconductor device may include a low-k dielectric layer formed on the trench. The low-k dielectric layer may be any of the low-k dielectric layers described in the present disclosure.

Aspects of the present disclosure provide a number of technical effects and benefits. For instance, a low-k dielectric layer on a surface of the N-polar Group III-nitride semiconductor structure may reduce an electric field proximate an electrode (e.g., gate contact) contacting the N-polar Group III-nitride semiconductor structure. The low-k dielectric layer may increase structural rigidity of the semiconductor device. A trench formed on the drain side of the N-polar Group III-nitride semiconductor structure may also reduce electric field and/or parasitic capacitances induced in the N-polar Group III-nitride semiconductor structure during operation of the semiconductor device. This may lead to increased performance of the semiconductor device, particularly at high frequencies, such as at frequencies of about 30 GHz or greater.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value. A used herein, generally perpendicular means within about 10° of perpendicular, such as truly perpendicular. As used herein, generally parallel means within about 10° of parallel such as truly parallel.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

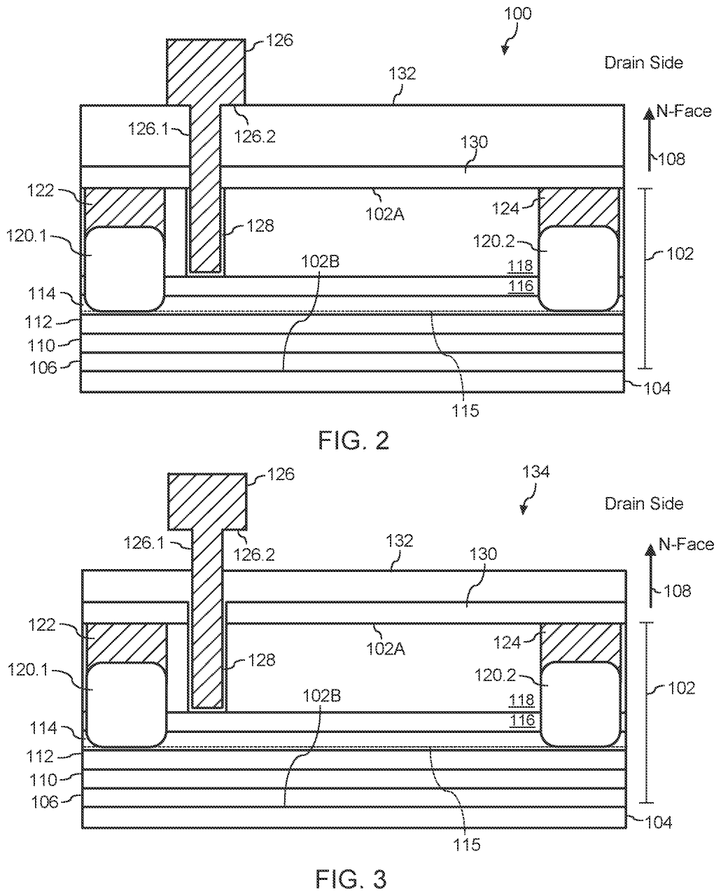

FIG. 2 depicts a cross-sectional view of an example HEMT device 100 according to example embodiments of the present disclosure. FIG. 2 is intended to represent structures for identification and description and is not intended to represent the structures to physical scale. The HEMT device 100 may include a semiconductor structure 102. The semiconductor structure 102 may be a Group III-nitride semiconductor structure, such as an N-polar Group III-nitride semiconductor structure. The semiconductor structure 102 may have a first surface 102A and a second surface 102B opposing the first surface 102A. The first surface 102A may be said to be on a “drain side” of the semiconductor device 100 as drain connections may be made on the side corresponding to the first surface 102A in semiconductor packages including the HEMT device 100.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN, ScAlN), and quaternary (e.g., AlInGaN, ScAlGaN) compounds. These compounds all have empirical formulas in which one mole of nitrogen is combined with a total of one mole of the Group III elements.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100. In some embodiments, the substrate 104 of the HEMT device 100 may be a thinned substrate 104. In some embodiments, the thickness of the substrate 104 may be about 100 μm or less, such as about 75 μm or less, such as about 50 μm or less.

The semiconductor structure 102 may include an optional nucleation layer 106 on the substrate 104. The nucleation layer 106 may be, for instance, a GaN layer and/or an AlN layer on the substrate 104 to provide a crystal structure transition between, for instance, a SiC substrate 104 and the Group III-nitride semiconductor structure 102. The nucleation layer 106 may be deposited on the substrate 104 using, for instance, metal-organic chemical vapor deposition (MOCVD), molecular beam epitaxy (MBE), or hydride vapor phase epitaxy (HVPE).

The semiconductor structure 102 may be an N-polar Group III-nitride semiconductor structure with an outward N-face in the growth direction 108 of the semiconductor structure 102. The semiconductor structure 102 may include several layers. In the example HEMT device 100 of FIG. 2, the semiconductor structure includes a buffer layer 110, a back barrier layer 112, a channel layer 114, a first cap layer 116, and a second cap layer 118. However, those of ordinary skill in the art, using the disclosures provided herein, will understand that aspects of the present disclosure are applicable to devices having semiconductor structures with different layer arrangements. The semiconductor structure 102 may be formed by epitaxial growth on the substrate 104. Techniques for epitaxial growth of Group III-nitrides have been described in, for example, U.S. Pat. Nos. 5,210,051, 5,393,993, and 5,523,589, the disclosures of which are incorporated by reference herein.

The buffer layer 110 may be an N-polar Group III nitride, such as AlᵥGa₁₋ᵥN, where 0≤v<0.1. In some embodiments, the aluminum mole fraction v is approximately 0 (e.g., 0.05 or less), indicating that the buffer layer 110 is GaN. The buffer layer 110 may or may not include other Group III-nitrides such as InGaN, AlInGaN or the like. The buffer layer 110 may be undoped or only unintentionally doped. In some examples, the buffer layer 110 may be iron doped to make the buffer layer semi-insulating. The buffer layer 110 may be grown to a thickness in the range of about 0.5 μm to about 5 μm, such as about 2 μm. The buffer layer 110 may be a multi-layer structure, such as a superlattice or combinations of GaN, AlGaN or the like. The buffer layer 110 may be under compressive strain in some embodiments.

The semiconductor structure 102 may include the back barrier layer 112 on the buffer layer 110. The back barrier layer 112 may be an N-polar Group III nitride, such as Al_{w}Ga_{1-w}N where 0.1≤w<0.4, indicating that the back barrier layer 112 is an AlGaN layer. In some embodiments, the back barrier layer 112 may be a ScAlN layer or a ScAlGaN layer. The back barrier layer 112 may or may not include other Group III-nitrides such as InGaN, AlInGaN or the like. The back barrier layer 112 may have a different band gap relative to the channel layer 114. The back barrier layer 112 may have a thickness in a range of about 250 Angstroms to about 350 Angstroms, such as about 300 Angstroms.

In some embodiments, the back barrier layer 112 may be a multilayer structure. For instance, in one example, the back barrier layer 112 may include a first layer of n+ doped GaN with a thickness of about 100 Angstroms. The back barrier layer 112 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The back barrier layer 112 may include a third layer of Al_{w.2}Ga_{1-w.2}N on the second layer, where w.2 is in a range of 0.3 to 0.4. The thickness of the third layer may be about 100 Angstroms. The back barrier layer 112 may include a fourth layer of AlN on the third layer. The thickness of the fourth layer may be in a range of about 5 Angstroms to about 15 Angstroms, such as about 7 Angstroms.

The semiconductor structure 102 may include the channel layer 114 on the back barrier layer 112. The channel layer 114 may be an N-polar Group III-nitride, such as AlₓGa₁₋ₓN, where 0≤x<0.1, provided that the energy of the conduction band edge of the channel layer 114 is less than the energy of the conduction band edge of the back barrier layer 112 at the interface between the channel layer 114 and the back barrier layer 112. The channel layer 114 may have a band gap that is different from the band gap of the back barrier layer 112. In some embodiments, the aluminum mole fraction x is approximately 0 (e.g., 0.05 or less), indicating that the channel layer 114 is GaN. The channel layer 114 may or may not include other Group III-nitrides such as InGaN, AlInGaN or the like. The channel layer 114 may have a thickness in a range of about 75 Angstroms to about 125 Angstroms, such as about 100 Angstroms.

A 2DEG 115 may be induced in the channel layer 114 at the interface between the channel layer 114 and the back barrier layer 112. The 2DEG 115 is highly conductive and allows conduction between the source and drain regions of the HEMT device 100. The 2DEG 115 may be controlled under operation of a gate, such that the HEMT device 100 acts as a controllable transistor device.

The semiconductor structure 102 includes a first cap layer 116 (e.g., an AlGaN cap layer) on the channel layer 114. The first cap layer 116 may be an N-polar Group III-nitride, such as Al_{y}Ga_{1-y}N where 0.1≤y<0.4, indicating that the first cap layer 116 is an AlGaN layer. In some embodiments, the aluminum mole fraction y is in a range of about 0.2 to about 0.3. In some embodiments, the first cap layer 116 may be a ScAlN layer or a ScAlGaN layer. The first cap layer 116 may or may not include other Group III-nitrides such as InGaN, AlInGaN or the like. The first cap layer may have a band gap that is different from the band gap of the channel layer 114. The first cap layer 116 may have a thickness in a range of about 15 Angstroms to about 50 Angstroms, such as about 26 Angstroms.

The semiconductor structure 102 includes a second cap layer 118 on the first cap layer 116. The second cap layer 118 may be an N-polar Group III-nitride, such as Al_{z}Ga_{1-z}N, where 0≤z<0.1. In some embodiments, the aluminum mole fraction z is approximately 0 (e.g., 0.05 or less), indicating that the second cap layer 118 is a GaN layer. The second cap layer 118 may or may not include other Group III-nitrides such as InGaN, AlInGaN or the like. The second cap layer 118 buries the channel layer 114 deep below the surface of semiconductor structure 102 such that the channel layer 114 is a buried layer at a depth of about 275 Angstroms or greater from the surface of the semiconductor structure 102, such as about 500 Angstroms or greater from the surface of the semiconductor structure 102, such as in a range of about 275 Angstroms to about 1000 Angstroms from the surface of the semiconductor structure 102. The second cap layer 118 may have a thickness in a range of about 250 Angstroms to about 1000 Angstroms, such as about 500 Angstroms.

The semiconductor structure 102 includes implanted regions 120.1 and 120.2. The implanted regions 120.1 and 120.2 include a distribution of implanted dopants (e.g., ions) of a first conductivity type such that the implanted regions 120.1 and 120.2 are n-type regions. The implanted regions 120.1 and 120.2 extend through the semiconductor structure 102 and into the channel layer 114.

The HEMT device 100 includes electrodes on the implanted regions 120.1 and 120.2. More particularly, the HEMT device 100 may include a source contact 122 on the implanted region 120.1. The HEMT device 100 may include a drain contact 124 on the implanted region 120.2. The source contact 122 and the drain contact 124 may be laterally spaced apart from each other. In some embodiments, the source contact 122 and the drain contact 124 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 122 may be an ohmic contact. The drain contact 124 may be an ohmic contact. In some embodiments, the source contact 122 and/or the drain contact 124 may include a plurality of layers to form an ohmic contact that may be provided as described, for example, in U.S. Pat. Nos. 8,563,372 and 9,214,352, the disclosures of which are incorporated by reference herein.

The HEMT device 100 may include a gate contact 126. The gate contact 126 may extend at least partially through a trench (e.g., an ALE defined trench) in the cap layer 118 so that the gate contact 126 is proximate to the first cap layer 116. In some examples, the gate contact 126 may have a gate length LG in a range of about 50 nm to about 150 nm. The gate length is the length of the gate contact 126 proximate to the first cap layer 116.

A passivation layer 128 may be located between the gate contact 126 and the first cap layer 116. The passivation layer 128 may be SiN. Other suitable dielectric layers may be used as the passivation layer 128, such as SiO₂, MgOx, MgNx, ZnO, SiNx, SiOx or other dielectric layers. The passivation layer 128 may be formed, for instance, using MOCVD process(s), atomic layer deposition (ALD) process(s), and/or sputter deposition processes. The passivation layer 128 may serve as a gate dielectric. In some examples, the passivation layer 128 may have a thickness, for instance, of about 5 Angstroms to about 100 Angstroms, such as about 10 Angstroms to about 50 Angstroms.

The gate contact 126 may be a T-shaped gate or a gamma gate, the formation of which is discussed by way of example in U.S. Pat. Nos. 8,049,252, 7,045,404, and 8,120,064, the disclosures of which are incorporated by reference herein. Materials capable of making a contact (e.g., a Schottky contact) to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSIN).

The HEMT device 100 may include additional passivation layer(s) 130 on the semiconductor structure 102, the gate contact 126, and/or other structures of the HEMT device 100. The additional passivation layer(s) 130 may be, for instance, dielectric materials, such as SiO₂, MgOx, MgNx, ZnO, SiNx, SiOx, alloys or layer sequences thereof. The additional passivation layer(s) 130 may be formed using MOCVD process(s), ALD process(s), sputter deposition process(s), or other suitable process(s). One or more insulating layers (not shown) may be on the HEMT device 100. For instance, the HEMT device 100 may be encapsulated in an insulating material without deviating from the scope of the present disclosure.

In some examples, the HEMT device 100 may be operable at frequencies of up to about 150 GHz. For instance, the HEMT device 100 may be operable at a frequency in a range of about 10 GHz to about 150 GHz, such as in a range of about 30 GHz to about 150 GHz, such as in a range of about 50 GHz to about 150 GHz. In some examples, the HEMT device 100 may have a power density of up to 10 W/mm or greater in these frequency ranges, such as a power density in a range of 2.5 W/mm to about 12 W/mm.

A transistor device cell may be formed by the active region between the source contact 122 and the drain contact 124 under the control of a gate contact 126 between the source contact 122 and the drain contact 124. FIG. 2 depicts a cross-sectional view of one device cell of an HEMT device 100 for purposes of illustration. The HEMT device 100 may be formed adjacent to additional HEMT device cells. In some examples, adjacent HEMT device cells may share contacts, such as source contacts.

According to example embodiments of the present disclosure, the HEMT device 100 includes a low-k dielectric layer 132 between the first surface 102A and at least a portion of an electrode (e.g., the gate contact 126). The low-k dielectric layer 132 is on the passivation layer 130 in the example of FIG. 2. However, in some embodiments, there may be no passivation layer 130. In these examples, the low-k dielectric layer 132 may be directly on the N-polar Group III-nitride semiconductor structure 102.

The low-k dielectric layer 132 may include a low-k dielectric material. The dielectric constant of the low-k dielectric layer 132 may be less than about 3.9. In some examples, the dielectric constant of the low-k dielectric layer 132 may be a range of greater than 1 and less than 3.9. In some examples, the low-k dielectric layer 132 includes one or more of a doped silicon dioxide, a porous silicon dioxide, an organic material, or a silicon-based polymeric material. The low-K dielectric layer 132 may be formed using MOCVD process(s), ALD process(s), sputter deposition process(s), or other suitable process(s).

As shown in FIG. 2, the gate contact 126 may include a first portion 126.1 on the N-polar Group III-nitride semiconductor structure 102. The gate contact 126 may include a second portion 126.2 on the first portion 126.1. The first portion 126.1 may be generally perpendicular to the first surface 102A of the N-polar Group III-nitride semiconductor structure 102. The second portion 126.2 may extend generally parallel to the first surface 102A of the N-polar Group III-nitride semiconductor structure 102. The first portion 126.1 of the gate contact 126 may extend into the N-polar Group III-nitride semiconductor structure 102. The second portion 126.2 may be spaced apart from the first surface 102A of the N-polar Group III-nitride semiconductor structure 102.

In the example of FIG. 2, the low-k dielectric layer 132 contacts the second portion 126.2 of the gate contact 126. More particularly, the low-k dielectric layer 132 fills a space between the N-polar Group III-nitride semiconductor structure 102 and the second portion 126.2. The low-k dielectric layer 132 can enhance the structural rigidity of the HEMT device 100. In addition, the low-dielectric layer 132 may reduce an electric field in the Group III-nitride semiconductor structure 102, such as in the channel layer 114 of the N-polar Group III-nitride semiconductor structure 102.

The low-k dielectric layer 132 may have other configurations without deviating from the scope of the present disclosure. For instance, FIG. 3 depicts a cross-sectional view of an example HEMT device 134 according to example embodiments of the present disclosure. FIG. 3 is intended to represent structures for identification and description and is not intended to represent the structures to physical scale. The HEMT device 134 may be similar to the HEMT device 100 of FIG. 2. However, the low-k dielectric layer 132 of the HEMT device 134 does not fill the space between the N-polar Group III-nitride semiconductor structure 102 and the second portion 126.2 of the gate contact 126. Rather, the low-k dielectric layer 132 of the HEMT device 134 partially fills the space between the N-polar Group III-nitride semiconductor structure 102 and the second portion 126.2 of the gate contact 126.

The low-k dielectric layer 132 is on the passivation layer 130 in the example of FIG. 3. However, in some embodiments, there may be no passivation layer 130. In these examples, the low-k dielectric layer 132 may be directly on the N-polar Group III-nitride semiconductor structure 102.

The low-k dielectric layer 132 may include a low-k dielectric material. The dielectric constant of the low-k dielectric layer 132 may be less than about 3.9. In some examples, the dielectric constant of the low-k dielectric layer 132 may be greater than 1 and less than 3.9. In some examples, the low-k dielectric layer 132 includes one or more of a doped silicon dioxide, a porous silicon dioxide, an organic material, or a silicon-based polymeric material. The low-K dielectric layer 132 may be formed using MOCVD process(s), ALD process(s), sputter deposition process(s), or other suitable process(s).

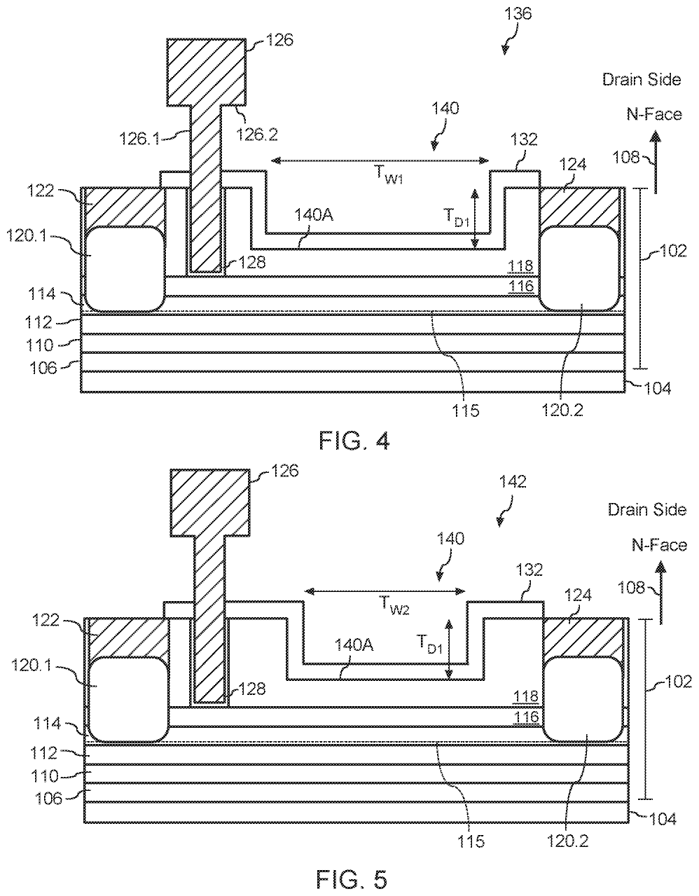

FIG. 4 depicts a cross-sectional view of an example HEMT device 136 according to example embodiments of the present disclosure. FIG. 4 is intended to represent structures for identification and description and is not intended to represent the structures to physical scale. The HEMT device 136 may be similar to the HEMT device 100 of FIG. 2. However, the HEMT device 136 includes a trench 140 defined on the drain side of the HEMT device 136. The trench 140 extends at least partially into one or more cap layers of the HEMT device 136, such as at least partially into the second cap layer 116.

The trench 140 may have a lateral width T_{W1} that extends between the gate contact 126 and the drain contact 124. The lateral width T_{W1} of the trench 140 may be in a range of about 0.25 μm to about 2 μm. The lateral width T_{W1} may be at least 50% of a distance between the gate contact and the drain contact, such as at least 75% of the distance between the gate contact and the drain contact, such as at least 85% of the distance between the gate contact and the drain contact, such as at least 90% of the distance between the gate contact and the drain contact.

The trench 140 may have a depth T_{D1} from a top surface of the N-polar Group III-nitride semiconductor structure. The depth T_{D1} may be such that the trench extends partially into the second cap layer 118. For instance, the depth T_{D1} may be about 250 Angstroms to about 500 Angstroms from a surface of the N-polar Group III-nitride semiconductor structure. The depth T_{D1} may be such that a lower surface 140A of the trench is within a certain distance from the channel layer 114. For instance, the depth T_{D1} may be such that the lower surface 140A is within about 250 Angstroms or less of a channel layer 114 in the N-polar Group III-nitride semiconductor structure 102, such as about 100 Angstroms or less.

In some examples, the trench 140 may have one or more dielectric layers, such as a dielectric layer 132 on the trench 140. In some examples, the dielectric layer 132 may include one or more dielectric materials, such as SiO₂, MgOx, MgNx, ZnO, SiNx, SiOx, alloys or layer sequences thereof. In some examples, the dielectric layer 132 may include a low-k dielectric material. The low-k dielectric may have a dielectric constant in a range of greater than 1 and less than 3.9. The dielectric layer 132 may be formed using MOCVD process(s), ALD process(s), sputter deposition process(s), or other suitable process(s). In some examples, the dielectric layer 132 may extend to a second portion 126.2 of the gate contact 126 to fill a space between the Group III-nitride semiconductor structure 102 and the second portion of the gate contact 126.

The trench may have varying depths and lateral widths. For instance, FIG. 5 depicts a cross-sectional view of an example HEMT device 142 according to example embodiments of the present disclosure. FIG. 5 is intended to represent structures for identification and description and is not intended to represent the structures to physical scale. The HEMT device 142 may be similar to the HEMT device 136 of FIG. 4. However, the trench 140 of the HEMT device 142 of FIG. 5 has a smaller lateral width T_{W2} relative to the lateral width T_{W1} of the HEMT device 136 of FIG. 4. For instance, the lateral width T_{W1} of the trench 140 may be in a range of about 0.25 μm to about 2 μm.

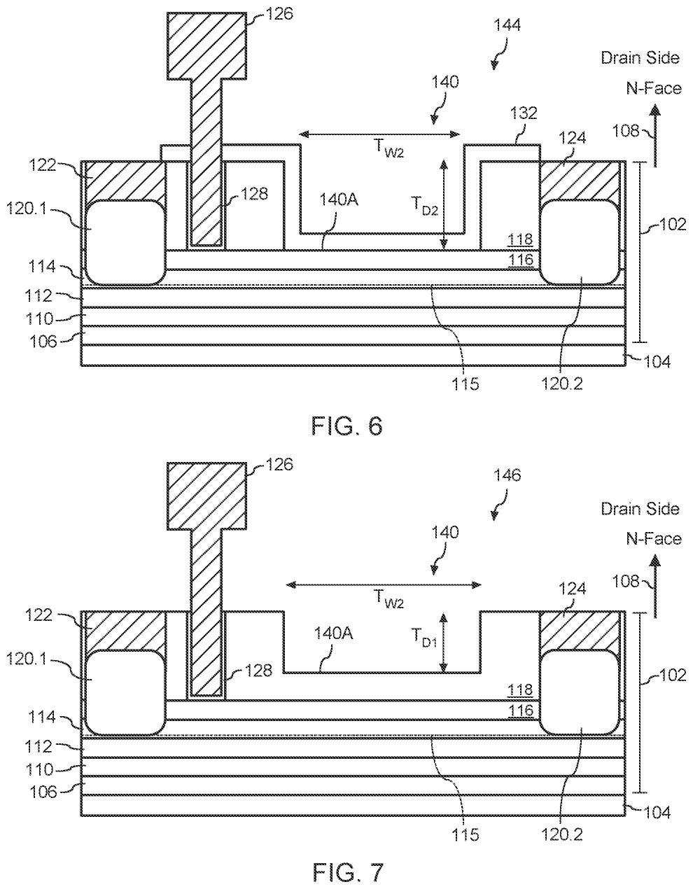

FIG. 6 depicts a cross-sectional view of an example HEMT device 144 according to example embodiments of the present disclosure. FIG. 6 is intended to represent structures for identification and description and is not intended to represent the structures to physical scale. The HEMT device 144 may be similar to the HEMT device 136 of FIG. 4. However, the trench 140 of the HEMT device 142 of FIG. 5 may have a depth T_{D2} that extends all the way through the cap layer 118. For instance, the trench 140 may have a depth T_{D2} that extends to an interface between the second cap lap layer 118 and the first cap layer 116. For instance, the depth T_{D2} may be about 500 Angstroms to about 1000 Angstroms from the surface 102A of the N-polar Group III-nitride semiconductor structure 102. The depth T_{D2} may be such that a lower surface 140A of the trench is within a certain distance from the channel layer 114. For instance, the depth T_{D2} may be such that the lower surface 140A is within about 250 Angstroms or less of a channel layer 114 in the N-polar Group III-nitride semiconductor structure 102, such as about 100 Angstroms or less, such as about 50 Angstroms or less, such as about 30 Angstroms or less.

Other variations may be made to these examples without deviating from the scope of the present disclosure. For instance, For instance, FIG. 7 depicts a cross-sectional view of an example HEMT device 146 according to example embodiments of the present disclosure. FIG. 7 is intended to represent structures for identification and description and is not intended to represent the structures to physical scale. The HEMT device 146 may be similar to the HEMT device 142 of FIG. 5. However, the HEMT device 146 does not include a dielectric layer on the trench 140.

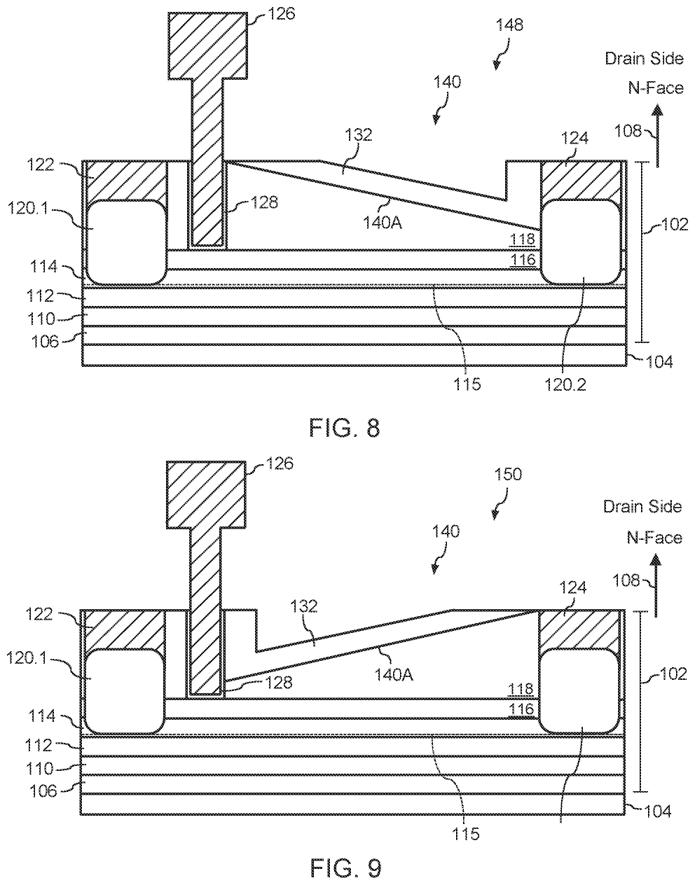

The lower surface of the trench 140 of any of the devices provided herein can have differing shapes without deviating from the scope of the present disclosure. For instance, FIG. 8 depicts a cross-sectional view of an example HEMT device 148 according to example embodiments of the present disclosure. FIG. 8 is intended to represent structures for identification and description and is not intended to represent the structures to physical scale. The HEMT device 148 may be similar to the HEMT device 136 of FIG. 4. However, the HEMT device 148 includes a trench 140 having a sloped lower surface 140A. The sloped lower surface 140A has a negative slope towards the drain contact 124.

FIG. 9 depicts a cross-sectional view of an example HEMT device 150 according to example embodiments of the present disclosure. FIG. 9 is intended to represent structures for identification and description and is not intended to represent the structures to physical scale. The HEMT device 150 may be similar to the HEMT device 136 of FIG. 4. However, the HEMT device 150 includes a trench 140 having a sloped lower surface 140A. The sloped lower surface 140A has a negative slope towards the gate contact 126.

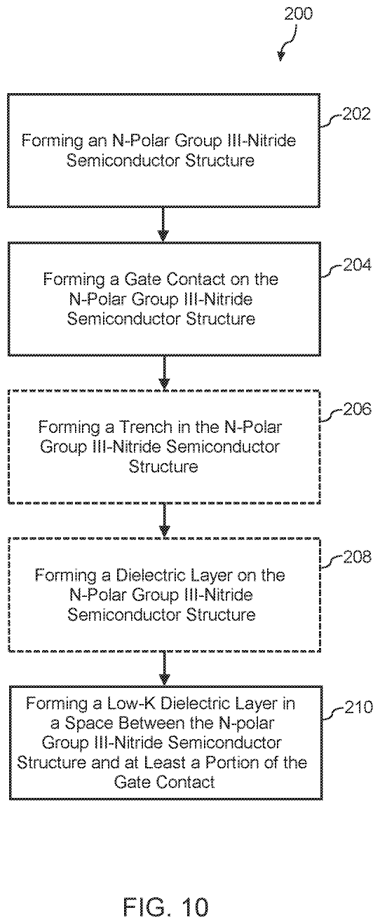

FIG. 10 depicts a flow chart of an example method 200 for fabricating a semiconductor device according to example embodiments of the present disclosure. FIG. 10 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 202, the method 200 may include forming an N-polar Group III-nitride semiconductor structure. For instance, the method 200 may include forming an N-polar Group III-nitride semiconductor substrate 102 on a substrate 104, such as a silicon carbide substrate 104. The semiconductor structure 102 may be a multilayer structure and may include one or more of a nucleation layer 106, a buffer layer 110, a barrier layer 112, a channel layer 114, a first cap layer 116 and second cap layer 118. Details concerning these example layers are described above with reference to FIG. 2. The N-polar Group III-nitride semiconductor structure may have a first surface 102A and a second surface 102B opposing the first surface 102A. The N-polar Group III-nitride semiconductor may be formed, for instance, by epitaxial growth. Techniques for epitaxial growth of Group III-nitrides have been described in, for example, U.S. Pat. Nos. 5,210,051, 5,393,993, and 5,523,589, the disclosures of which are incorporated by reference herein.

At 204, the method 200 may include forming a gate contact on the N-polar Group III-nitride semiconductor structure. For instance, the method may include forming the gate contact 126 on the N-polar Group III-nitride semiconductor structure 102 of FIG. 2. The gate contact may be a T-gate or a gamma gate, the formation of which is discussed by way of example in U.S. Pat. Nos. 8,049,252, 7,045,404, and 8,120,064, the disclosures of which are incorporated by reference herein.

At 206, the method 200 may optionally including forming a trench in the N-polar Group III-nitride semiconductor structure. For instance, the trench may be formed in a cap layer of the N-polar Group III-nitride semiconductor structure. The trench may have a lateral width extending between the gate contact and a drain contact. Example trenches 140 are depicted in FIGS. 4-9. The trench may be formed in any suitable manner, such as using an etch process (e.g., wet etch, plasma-based dry etch, atomic layer etch, etc.).

At 208, the method 200 may optionally include forming a dielectric layer on the Group III-nitride semiconductor structure. The dielectric layer may be, for instance, the passivation layer 130 discussed with reference to FIG. 2. The dielectric layer may be, for instance, dielectric materials, such as SiO₂, MgOx, MgNx, ZnO, SiNx, SiOx, alloys or layer sequences thereof. The dielectric layer may be formed using MOCVD process(s), ALD process(s), sputter deposition process(s), or other suitable process(s).

At 210, the method 200 may include forming a low-k dielectric layer in a space between the N-polar Group III-nitride semiconductor structure and at least portion of the gate contact. For instance, the method may include forming the low-k dielectric layer 132 of FIG. 2 or 3. Forming the low-k dielectric layer may include forming the low-k dielectric layer such that the low-k dielectric layer contacts the second portion of the gate contact. The low-k dielectric layer may have a dielectric constant of less than about 3.9, such as in a range of greater than 1 and less than 3.9. In some examples, the low-k dielectric layer may include one or more of a doped silicon dioxide, a porous silicon dioxide, an organic material, or a silicon-based polymeric material. The low-k dielectric layer may be formed using MOCVD process(s), ALD process(s), sputter deposition process(s), or other suitable process(s).

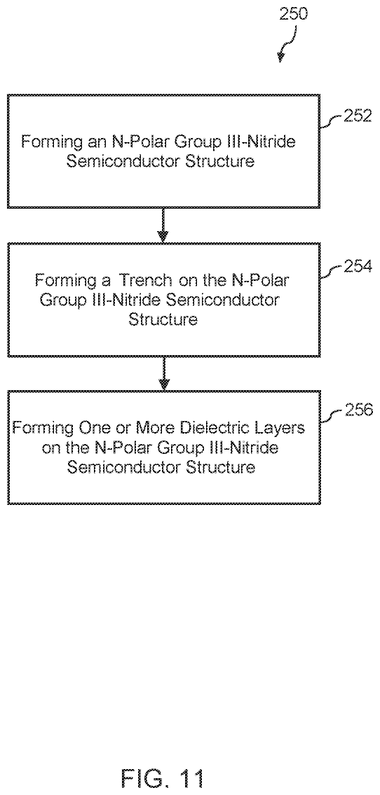

FIG. 11 depicts a flow chart of an example method 250 for fabricating a semiconductor device according to example embodiments of the present disclosure. FIG. 11 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 252, the method 250 may include forming an N-polar Group III-nitride semiconductor structure. For instance, the method 250 may include forming an N-polar Group III-nitride semiconductor substrate 102 on a substrate 104, such as a silicon carbide substrate 104. The semiconductor structure 102 may be a multilayer structure and may include one or more of a nucleation layer 106, a buffer layer 110, a barrier layer 112, a channel layer 114, a first cap layer 116 and second cap layer 118. Details concerning these example layers are described above with reference to FIG. 2. The N-polar Group III-nitride semiconductor structure may have a first surface 102A and a second surface 102B opposing the first surface 102A. The N-polar Group III-nitride semiconductor may be formed, for instance, by epitaxial growth. Techniques for epitaxial growth of Group III-nitrides have been described in, for example, U.S. Pat. Nos. 5,210,051, 5,393,993, and 5,523,589, the disclosures of which are incorporated by reference herein.

At 254, the method 250 may include forming a trench in the N-polar Group III-nitride semiconductor structure. For instance, the trench may be formed in a cap layer of the N-polar Group III-nitride semiconductor structure. The trench may have a lateral width extending between the gate contact and a drain contact. Example trenches 140 are depicted in FIGS. 4-9. The trench may be formed in any suitable manner, such as using an etch process (e.g., wet etch, plasma-based dry etch, atomic layer etch, etc.).

At 256, the method 250 may include forming one or more dielectric layers on the N-polar Group III-nitride semiconductor structure. For instance, the method 250 may include forming one or more dielectric layers on the trench. In some examples, the one or more dielectric layers may include, for instance, dielectric materials, such as SiO₂, MgOx, MgNx, ZnO, SiNx, SiOx, alloys or layer sequences thereof. In some examples, the one or more dielectric layers may include a low-k dielectric layer. The low-k dielectric layer may have a dielectric constant of less than about 3.9, such as in a range of greater than 1 and less than 3.9. In some examples, the low-k dielectric layer may include one or more of a doped silicon dioxide, a porous silicon dioxide, an organic material, or a silicon-based polymeric material. The dielectric layer may be formed using MOCVD process(s), ALD process(s), sputter deposition process(s), or other suitable process(s).

Example aspects of the present disclosure are set forth below. Any of the below features or examples may be used in combination with any of the embodiments or features provided in the present disclosure.

One example aspect of the present disclosure is directed to a semiconductor device. The semiconductor device may include a nitrogen polar (N-polar) Group III-nitride semiconductor structure. The N-polar Group III-nitride semiconductor structure may have a first surface and a second surface opposing the first surface. The semiconductor device may include an electrode. The semiconductor device may include a low-k dielectric layer located between the first surface of the N-polar Group III-nitride semiconductor structure and at least a portion of the electrode. The low-k dielectric layer may have a dielectric constant of less than about 3.9.

In some embodiments, the dielectric constant of the low-k dielectric layer is greater than 1. In some embodiments, the low-k dielectric layer comprises one or more of a doped silicon dioxide, a porous silicon dioxide, an organic material, or a silicon-based polymeric material.

In some embodiments, the electrode comprises a first portion on the N-polar Group III-nitride semiconductor structure and a second portion on the first portion, the first portion extending generally perpendicular to the first surface of the N-polar Group III-nitride semiconductor structure and the second portion extending generally parallel to the first surface of the N-polar Group III-nitride semiconductor structure. In some embodiments, the first portion of the electrode extends into the N-polar Group III-nitride semiconductor structure. In some embodiments, the second portion of the electrode is spaced apart from the first portion of the N-polar Group III-nitride semiconductor structure. In some embodiments, the low-k dielectric layer contacts the second portion of the electrode. In some embodiments, the low-k dielectric layer fills a space defined between the first surface of the N-polar Group III-nitride semiconductor structure and the second portion of the electrode.

In some embodiments, the electrode is a gate contact. In some embodiments, the gate contact is a T-gate contact or a gamma-gate contact.

In some embodiments, the semiconductor device further comprises a second dielectric layer between the low-k dielectric layer and the N-polar Group III-nitride structure. IN some embodiments the second dielectric layer comprises silicon nitride. In some embodiments, the low-k dielectric layer fills a space defined between the second dielectric layer and at least portion of the electrode.

In some embodiments, the Group III-nitride semiconductor structure comprises a barrier layer, a channel layer, and one or more cap layers, wherein the Group III-nitride semiconductor structure comprises a trench extending at least partially into the one or more cap layers. In some embodiments, the trench has a lateral width extending between a gate contact and a drain contact. In some embodiments, the lateral width is about 50% or greater of a distance between the gate contact and the drain contact. In some embodiments, the trench extends to a depth from the first surface of about 250 Angstroms to about 1000 Angstroms.

In some embodiments, the N-polar Group III-nitride semiconductor structure has a nitrogen face in a growth direction of the Group III-nitride semiconductor structure.

In some embodiments, the semiconductor device comprises a silicon carbide substrate.

In some embodiments, the semiconductor device is a high electron mobility transistor device.

Another example aspect of the present disclosure is directed to a transistor device. The transistor device may include an N-polar Group III-nitride semiconductor structure. The N-polar Group III-nitride semiconductor structure may include a barrier layer, a channel layer on the barrier layer, and one or more cap layers on the channel layer. The transistor device may include a trench extending at least partially into the one or more cap layers of the N-polar Group III-nitride semiconductor structure.

In some embodiments, the barrier layer comprises Al_{w}Ga_{1-w}N, where w is in a range of about 0.1 to about 0.4; and the channel layer comprises AlₓGa₁₋ₓN, where x is less than about 0.1.

In some embodiments, the one or more cap layers comprise a first cap layer and a second cap layer, wherein the first cap layer comprises Al_{y}Ga_{1-y}N, where y is in a range of about 0.1 to about 0.4, and wherein the second cap layer comprises Al_{z}Ga_{1-z}N, where w is in less than about 0.1. In some embodiments, the second cap layer has a thickness in a range of about 250 Angstroms to about 1000 Angstroms.

In some embodiments, the trench has a depth that extends through the second cap layer to an interface between the second cap layer and the first cap layer. In some embodiments, the trench has a depth of about 250 Angstroms to about 1000 Angstroms. In some embodiments, a lower surface of the trench is within about 250 Angstroms or less of the channel layer.

In some embodiments, the transistor device comprises a gate contact and a drain contact. In some embodiments, the trench has a lateral width that extends at least partially between the gate contact and the drain contact. In some embodiments, the lateral width is about 50% or greater of a distance between the gate contact and the drain contact.

In some embodiments, the trench has a sloped lower surface with a negative slope toward the gate contact. In some embodiments, the trench has a sloped lower surface with a negative slope toward the drain contact.

In some embodiments, the transistor device further comprises one or more dielectric layers. In some embodiments, the one or more dielectric layers comprise silicon nitride. In some embodiments, the one or more dielectric layers comprise a low-k dielectric material having a dielectric constant in a range of greater than 1 and less than 3.9.

In some embodiments, the N-polar Group III-nitride semiconductor structure has a nitrogen face in a growth direction of the N-polar Group III-nitride semiconductor structure.

In some embodiments, the transistor device comprises a silicon carbide substrate.

In some embodiments, the transistor device is a high electron mobility transistor device.

Another example aspect of the present disclosure is directed to a transistor device. The transistor device may include an N-polar Group III-nitride semiconductor structure. The N-polar Group III-nitride semiconductor structure may include a barrier layer and a channel layer on the barrier layer. The transistor device may include a gate contact. The transistor device may include a low-k dielectric layer located between a first surface of the N-polar Group III-nitride semiconductor structure and at least a portion of the gate contact. The low-k dielectric layer may have a dielectric constant of less than about 3.9.

In some embodiments, the dielectric constant of the low-k dielectric layer is greater than about 1. In some embodiments, the low-k dielectric layer comprises one or more of a doped silicon dioxide, a porous silicon dioxide, an organic material, or a silicon-based polymeric material.

In some embodiments, the barrier layer comprises Al_{w}Ga_{1-w}N, where w is in a range of about 0.1 to about 0.4; and the channel layer comprises AlₓGa₁₋ₓN, where x is less than about 0.1.

In some embodiments, the gate contact comprises a first portion on the N-polar Group III-nitride semiconductor structure and a second portion on the first portion, the first portion extending generally perpendicular to the first surface of the N-polar Group III-nitride semiconductor structure and the second portion extending generally parallel to the first surface of the N-polar Group III-nitride semiconductor structure. In some embodiments, the first portion of the gate contact extends into the N-polar Group III-nitride semiconductor structure. In some embodiments, the second portion of the gate contact is spaced apart from the first portion of the N-polar Group III-nitride semiconductor structure. In some embodiments, the low-k dielectric layer contacts the second portion of the gate contact. In some embodiments, the low-k dielectric layer fills a space defined between the first surface of the N-polar Group III-nitride semiconductor structure and the second portion of the gate contact.

In some embodiments, the transistor device further comprises a second dielectric layer between the low-k dielectric layer and the N-polar Group III-nitride structure. In some embodiments, the second dielectric layer comprises silicon nitride. In some embodiments, the low-k dielectric layer fills a space defined between second dielectric layer and at least a portion of the gate contact.

In some embodiments, the N-polar Group III-nitride semiconductor structure comprises a first cap layer and a second cap layer, wherein the first cap layer comprises Al_{y}Ga_{1-y}N, where y is in a range of about 0.1 to about 0.4, and wherein the second cap layer comprises Al_{z}Ga_{1-z}N, where w is in less than about 0.1. In some embodiments, the second cap layer has a thickness in a range of about 250 Angstroms to about 1000 Angstroms.

In some embodiments, the transistor device further comprises a trench extending at least partially through the second cap layer. In some embodiments, a lateral width of the trench extends between a gate contact and a drain contact. In some embodiments, the trench has a sloped lower surface with a negative slope toward the gate contact. In some embodiments, the trench has a sloped lower surface with a negative slope toward the drain contact.

Yet another example aspect of the present disclosure is directed to a method. The method may include forming an N-polar Group III-nitride semiconductor structure. The method may include forming a gate contact on the N-polar Group III-nitride semiconductor structure. The method may include forming a low-k dielectric layer in a space between the N-polar Group III-nitride semiconductor structure and at least a portion of the gate contact. The low-k dielectric layer has a dielectric constant of less than about 3.9.

In some embodiments, the method further comprises forming a second dielectric layer on the N-polar Group III-nitride semiconductor structure, wherein the low-k dielectric layer is formed on the second dielectric layer.

In some embodiments, the gate contact comprises a first portion on the N-polar Group III-nitride semiconductor structure and a second portion on the first portion, the first portion extending generally perpendicular to a surface of the N-polar Group III-nitride semiconductor structure and the second portion extending generally parallel to the surface of the N-polar Group III-nitride semiconductor structure.

In some embodiments, forming the low-k dielectric layer comprises forming the low-k dielectric layer such that it contacts the second portion of the gate contact.

In some embodiments, the method further comprises forming a trench in the N-polar Group III-nitride structure. In some embodiments, the trench has a lateral width extending between the gate contact and a drain contact. In some embodiments, the trench has a sloped lower surface with a negative slope toward the gate contact. In some embodiments, the trench has a sloped lower surface with a negative slope toward the drain contact.

Yet another example aspect of the present disclosure is directed to a method. The method may include forming an N-polar Group III-nitride semiconductor structure. The N-polar Group III-nitride semiconductor structure may include a barrier layer, a channel layer on the barrier layer, and one or more cap layers on the channel layer. The method may include forming a trench at least partially extending through the one or more cap layers.

In some embodiments, the trench has a lateral width extending between a gate contact and a drain contact. In some embodiments, the trench has a sloped lower surface with a negative slope toward the gate contact. In some embodiments, the trench has a sloped lower surface with a negative slope toward the drain contact.

In some embodiments, the method comprises forming one or more dielectric layers on the trench. In some embodiments, the one or more dielectric layers comprise silicon nitride. In some embodiments, the one or more dielectric layers comprise a low-k dielectric layer having a dielectric constant of less than about 3.9.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a nitrogen polar (N-polar) Group III-nitride semiconductor structure, the N-polar Group III-nitride semiconductor structure having a first surface and a second surface opposing the first surface;
an electrode;
a low-k dielectric layer located between the first surface of the N-polar Group III-nitride semiconductor structure and at least a portion of the electrode; and
wherein the low-k dielectric layer has a dielectric constant of less than about 3.9.

2. The semiconductor device of claim 1, wherein the dielectric constant of the low-k dielectric layer is greater than 1.

3. The semiconductor device of claim 1, wherein the low-k dielectric layer comprises one or more of a doped silicon dioxide, a porous silicon dioxide, an organic material, or a silicon-based polymeric material.

4. The semiconductor device of claim 1, wherein the electrode comprises a first portion on the N-polar Group III-nitride semiconductor structure and a second portion on the first portion, the first portion extending generally perpendicular to the first surface of the N-polar Group III-nitride semiconductor structure and the second portion extending generally parallel to the first surface of the N-polar Group III-nitride semiconductor structure.

5. The semiconductor device of claim 4, wherein the first portion of the electrode extends into the N-polar Group III-nitride semiconductor structure.

6. The semiconductor device of claim 4, the second portion of the electrode is spaced apart from the first portion of the N-polar Group III-nitride semiconductor structure.

7. The semiconductor device of claim 6, wherein the low-k dielectric layer contacts the second portion of the electrode.

8. The semiconductor device of claim 6, wherein the low-k dielectric layer fills a space defined between the first surface of the N-polar Group III-nitride semiconductor structure and the second portion of the electrode.

9. The semiconductor device of claim 1, wherein the electrode is a gate contact, wherein the gate contact is a T-gate contact or a gamma-gate contact.

10. (canceled)

11. The semiconductor device of claim 1, wherein the semiconductor device further comprises a second dielectric layer between the low-k dielectric layer and the N-polar Group III-nitride structure.

12. The semiconductor device of claim 11, wherein the second dielectric layer comprises silicon nitride.

13. The semiconductor device of claim 11, wherein the low-k dielectric layer fills a space defined between the second dielectric layer and at least portion of the electrode.

14. The semiconductor device of claim 1, wherein the Group III-nitride semiconductor structure comprises a barrier layer, a channel layer, and one or more cap layers, wherein the Group III-nitride semiconductor structure comprises a trench extending at least partially into the one or more cap layers.

15. The semiconductor device of claim 14, wherein the trench has a lateral width extending between a gate contact and a drain contact.

16. The semiconductor device of claim 15, wherein the lateral width is about 50% or greater of a distance between the gate contact and the drain contact.

17. The semiconductor device of claim 15, wherein the trench extends to a depth from the first surface of about 250 Angstroms to about 1000 Angstroms.

18. (canceled)

19. The semiconductor device of claim 1, wherein the semiconductor device comprises a silicon carbide substrate.

20. The semiconductor device of claim 1, wherein the semiconductor device is a high electron mobility transistor device.

21. A transistor device, comprising:
a nitrogen polar (N-polar) Group III-nitride semiconductor structure, the N-polar Group III-nitride semiconductor structure comprising:
a barrier layer;
a channel layer on the barrier layer; and
one or more cap layers on the channel layer; and
wherein the transistor device comprises a trench extending at least partially into the one or more cap layers of the N-polar Group III-nitride semiconductor structure.

22.-56. (canceled)

57. A method, comprising:
forming an N-polar Group III-nitride semiconductor structure;
forming a gate contact on the N-polar Group III-nitride semiconductor structure; and
forming a low-k dielectric layer in a space between the N-polar Group III-nitride semiconductor structure and at least a portion of the gate contact; and
wherein the low-k dielectric layer has a dielectric constant of less than about 3.9.

58.-71. (canceled)
